(19) United States
(12) Patent Application Publication
(10) Pub. No.: US 2006/0185714 A1
(43) Pub. Date: Aug. 24, 2006

(54) Flexible solar cell and method of producing the same

(75) Inventors: Jung-gyu Nam, Yongin-si (KR); Sang-cheol Park, Seoul (KR); Won-cheol Jung, Seoul (KR); Young-jun Park, Suwon-si (KR)

Correspondence Address: BUCHANAN INGERSOLL PC;(INCLUDING BURNS, DOANE, SWECKER & MATHIS), POST OFFICE BOX 1404, ALEXANDRIA, VA, 22313-1404, US

(73) Assignee: Samsung Electronics Co., Ltd., Suwon-si (KR)

(21) Appl. No.: 11/346,212

(22) Filed: Feb. 3, 2006

(30) Foreign Application Priority Data
Feb. 5, 2005 (KR) 10-2005-0010990

(51) Int. Cl. H01L 31/042

(52) U.S. Cl. 136/244; 136/251

(57) ABSTRACT

Provided are a cylindrical flexible solar cell which is made of only flexible materials so that the cell can freely bend, has a cylindrical shape which allows the cell to absorb solar light at any angle of illumination, and has a large surface area and high efficiency; and a method of producing the same.

### CROSS-REFERENCE TO RELATED PATENT APPLICATION

Prioirty is claimed to Korean Patent Application No. 10-2005-0010990, filed on Feb. 5, 2005, in the Korean Intellectual Property Office, the disclosure of which is incorporated herein in its entirety by reference.

### BACKGROUND OF THE DISCLOSURE

1. Field of the Disclosure

The present disclosure relates to a cylindrical flexible solar cell and a method of producing the same, and more particularly, to a cylindrical flexible solar cell which is made of only flexible materials so that the cell can freely bend, has a cylindrical shape which allows the cell to absorb solar light at any angle of illumination, and has a large surface area and high efficiency, and a method of producing the same.

2. Description of the Related Art

In an attempt to address recent energy-related problems, research has been carried out to find replacements for existing fossil fuels. In particular, extensive research has been carried out to utilize natural energy such as wind energy, nuclear energy, solar energy and the like to replace the petroleum resources that are expected to undergo exhaustion within several decades. Among the possible replacements, solar cells utilizing solar energy are promising because, unlike other energy resources, the energy resource is unlimited and is environmentally friendly. Solar cells were first developed in 1983, and silicone solar cells have recently come into the spotlight.

However, silicone solar cells have very high production costs, which make it difficult to practicalize the cells, and there are difficulties in improving the cell efficiency of silicone solar cells. In order to overcome these problems, research is being carried out to develop dye-sensitized solar cells which are produced at significantly low costs.

A dye-sensitized solar cell is a photovoltaic solar cell containing photosensitive dye molecules that are capable of generating electron-hole pairs by absorbing visible light, unlike silicone solar cells. A dye-sensitized solar cell also contains a transition metal oxide that transfers generated electrons. A representative example of the dye-sensitized solar cells known so far is a solar cell disclosed by Graetzel et al. in Switzerland in 1991. The solar cell produced by Graetzel et al. consists of a semiconductor electrode made of nanoparticulate titanium dioxide (TiO₂) and coated with dye molecules, a counter electrode (platinum electrode), and an electrolyte filling the gap between the electrodes. Since this cell can be produced at a lower production cost per unit electric power than conventional silicone solar cells, the cell is drawing much attention as a possible replacement for the existing solar cells.

FIG. 1 illustrates the structure of a dye-sensitized solar cell. According to FIG. 1, the dye-sensitized solar cell includes a semiconductor electrode 10, an electrolyte layer 13 and a counter electrode 14. The semiconductor electrode 10 consists of a conductive transparent substrate 11 and a light absorbing layer 12, and the semiconductor electrode 10 is formed by coating a conductive transparent substrate with a colloidal solution of nanoparticulate oxide, heating the coated substrate in an electric furnace at a high temperature, and then adsorbing a dye thereon. Here, the purpose of heating the colloid-coated electrode at a high temperature is to remove organic materials such as polymers that have been added to enhance electrical contact between the oxide nanoparticles and to facilitate the process of producing the colloidal solution, thereby stabilizing the light absorbing layer. In general, the heating temperature is relatively high, in the range of 450 to 500° C., and a glass substrate can be used at such high temperature without deformation. Thus, a glass substrate is widely used as the conductive transparent substrate. However, since it is impossible to bend a solar cell produced with a glass substrate, the substrate is rarely used in applications where flexible solar cells are needed.

Bendable dye-sensitized solar cells have increasingly attracted interest since 2000. According to the research results reported so far, flexible solar cells are classified into those in which the nanoparticulate oxide layer is produced by applying a colloidal solution having oxide nanoparticles dispersed in a solvent which is volatile at a low temperature, such as ethanol, and then subjecting the applied colloidal solution to heat treatment at a temperature of around 100° C.; and those in which the nanoparticulate oxide layer is produced by applying a colloidal solution containing an organic dispersant and then removing the dispersant by means of UV irradiation and heating at a temperature around 100° C.

However, these solar cells exhibit low photovoltaic conversion efficiencies compared to the conventional dye-sensitized solar cells using glass substrates.

Meanwhile, Japanese Unexamined Patent Application No. 2003-77550 describes a solar cell formed into a cylindrical shape or a semi-cylindrical shape so as to increase the surface area for receiving solar light. However, this solar cell is a result of mere modification of the shape and an increase in the effective area for power generation per area of cell installation, and thus substantial improvement in the photovoltaic conversion efficiency cannot be achieved. Further, use of a glass substrate as the conductive transparent substrate makes bending of the cell impossible.

### SUMMARY OF THE DISCLOSURE

The present disclosure provides a cylindrical flexible solar cell which is capable of bending and has improved photovoltaic conversion efficiency.

The present disclosure also provides a cylindrical flexible bilayer solar cell which is capable of bending and has improved photovoltaic conversion efficiency.

The present disclosure also provides a method of producing a cylindrical flexible solar cell.

According to an aspect of the present disclosure, there is provided a cylindrical flexible solar cell including: a cylindrical flexible waveguide; a flexible counter electrode disposed around the waveguide; a flexible light absorbing layer that is disposed around the counter electrode and has a sensitizer adsorbed thereon; a conductive transparent electrode layer disposed around the flexible light absorbing layer; and a flexible electrolyte layer interposed between the light absorbing layer and the counter electrode.

A cylindrical flexible solar cell according to the present disclosure includes: a cylindrical flexible waveguide; a flexible conductive transparent electrode disposed adjacent to the waveguide; a first flexible light absorbing layer that is disposed around the flexible conductive transparent electrode and has a sensitizer adsorbed thereon; a counter electrode disposed around the flexible light absorbing layer; a second flexible light absorbing layer that is disposed around the counter electrode and has a sensitizer adsorbed thereon; a conductive transparent electrode layer disposed around the second flexible light absorbing layer; and a flexible electrolyte layer respectively interposed between the first and second light absorbing layers and the counter electrode.

According to an embodiment of the present disclosure, there is provided a method of producing a flexible solar cell comprising: coating a cylindrical flexible waveguide with a material to form a counter electrode; coating the counter electrode with a flexible electrolyte layer; coating the flexible electrolyte layer with a light absorbing layer having a sensitizer adsorbed thereon; and subjecting the light absorbing layer to heat treatment after the coating and then coating the light absorbing layer with a conductive flexible transparent substrate.

A method of producing a flexible solar cell according to the present disclosure comprises: coating a cylindrical flexible waveguide with a first conductive flexible transparent substrate; coating the conductive flexible transparent substrate with a first light absorbing layer and subjecting the first light absorbing layer to heat treatment; adsorbing a sensitizer onto the first light absorbing layer; coating the sensitizer with an electrolyte layer and then coating the electrolyte layer with a flexible counter electrode; coating the counter electrode with a flexible electrolyte layer; coating the flexible electrolyte layer with a second light absorbing layer having a sensitizer adsorbed thereon; and subjecting the second light absorbing layer to heat treatment after the coating of the flexible electrolyte layer and then coating the second light absorbing layer with a second conductive flexible transparent substrate.

A method of producing a cylindrical flexible solar cell according to the present disclosure comprises: preparing slurries for conductive flexible transparent substrates, flexible light absorbing layers, sensitizers, flexible electrolyte layers, a flexible counter electrode and a flexible waveguide, respectively; arranging slurry discharge nozzles in order for a conductive flexible transparent substrate, a flexible light absorbing layer, a sensitizer, a flexible electrolyte layer, a flexible counter electrode, and a flexible waveguide; or in order for a conductive flexible transparent substrate, a first flexible light absorbing layer, a first sensitizer, a first flexible electrolyte layer, a flexible counter electrode, a second flexible electrolyte layer, a second sensitizer, a second flexible light absorbing layer, and a flexible waveguide; discharging the slurries through an electrospinning apparatus to form a wire; and then subjecting the wire to heat treatment.

### BRIEF DESCRIPTION OF THE DRAWINGS

The above and other features and advantages of the present invention will become more apparent by describing in detail exemplary embodiments thereof with reference to the attached drawings in which:

FIG. 1 is a schematic diagram of a cylindrical flexible solar cell according to an embodiment of the present invention;

FIG. 2 is a cross-sectional view illustrating the process of light absorption by the cylindrical flexible solar cell of FIG. 1;

FIG. 3 is a schematic diagram of a cylindrical flexible solar cell having a bilayer structure according to an embodiment of the present invention;

FIG. 4 is a cross-sectional view illustrating the process of light absorption by the cylindrical flexible solar cell having a bilayer structure of FIG. 3;

FIGS. 5 through 7 respectively illustrate applications of a cylindrical flexible solar cell according to an embodiment of the present invention;

FIG. 8 is a schematic diagram of a cylindrical flexible solar cell according to an embodiment of the present invention;

FIG. 9 is a cross-sectional view illustrating the process of light absorption in the cylindrical flexible solar cell of FIG. 8; and

FIG. 10 illustrates an electrospinning apparatus.

### DETAILED DESCRIPTION OF EXEMPLARY EMBODIMENTS

Hereinafter, the present invention will be described in more detail.

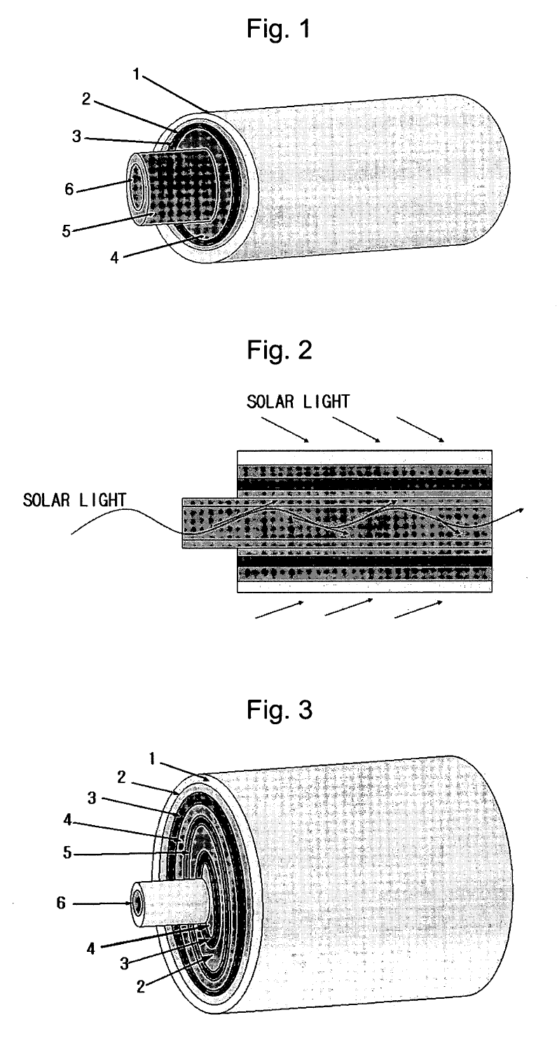

Referring to FIG. 1, the solar cell according to an embodiment of the present invention includes a cylindrical waveguide 6, a counter electrode 5 surrounding the waveguide 6, an electrolyte layer 4 surrounding the counter electrode 5, and a semiconductor electrode surrounding the electrolyte layer 4. The semiconductor electrode include a conductive transparent substrate 1, a light absorbing layer 2 (metal oxide layer) and a sensitizer 3 (dye).

The solar cell according to an embodiment of the present invention is cylindrical, and thus is capable of absorbing light from external sources, regardless of where the external source is, to generate electricity stably for a long time. The solar cell is also advantageous in that a smaller area for installation is needed than for planar solar cells. Furthermore, since this implies that light enters the waveguide 6 without passing through the semiconductor electrode, etc. disposed at the center and is scattered and absorbed internally in the cell, the photovoltaic conversion efficiency is increased. In particular, the materials forming the respective element layers are flexible and bendable, and thus the resulting solar cell has a wide range of applications compared to conventional rigid solar cells.

In the solar cell according to the present embodiment, the waveguide 6 disposed at the center refracts and reflects the light incident from the lateral sides of the cell and transmits the incident light to the counter electrode 5. That is, while conventional planar cells and cylindrical cells absorb light only on the external surface, the cylindrical solar cell of the present embodiment induces transmittance and absorption of light along the centrally located waveguide 6 and makes it possible to use the received light more efficiently. In other words, the disposition of the waveguide 6 at the center of the solar cell enables 100% utilization of light that is incident from all directions.

The waveguide 6 having such a feature is not particularly limited in type, and may be any waveguide conventionally used in the field of electric cells. In general, the main purpose of using a waveguide is to transmit light without light leakage to the outside, but the waveguide 6 of the present embodiment can satisfy the dual purpose of transmission and absorption of light at the same time. To this end, the refractive indices of the counter electrode 5 and the waveguide 6 should be taken into account; for example, the ratio of the refractive index of the counter electrode 5 to that of the waveguide 6 with respect to the light entering the waveguide can be less than or equal to 1. This implies that the reflection of more light can be induced, and a larger amount of light can be transmitted to the inside of the cell. When the ratio of the refractive indices is close to 1, a larger amount of light is transmitted to the counter electrode 5; on the other hand, when the ratio of the refractive index of the counter electrode 5 to the refractive index of the waveguide 6 is close to 0, the range of the incident angle where total reflection occurs increases, and more light can be transmitted to the inside of the waveguide 6, while the amount of light transmitted to the counter electrode 5 is reduced. The bendable (flexible) waveguide 6 which satisfies such requirements may include an optical fiber, a conductive polymer, a composite material of carbon nanotubes mixed in a conductive polymer, a conductive transparent electrode or the like. It is also possible to use air as the material for the waveguide 6, because since air can obtain the desired effect, and a transparent substrate forming the counter electrode 5 adequately absorbs and reflects the incident light. The diameter of the waveguide 6 can be appropriately selected according to the use of the cell, and may range from 1 mm to 10 mm in consideration of the transmission and reflection of light.

Counter electrode 5 disposed on the periphery of the waveguide 6 to be in contact with the waveguide 6. The counter electrode 5 can be made of any flexible conductive material without being particularly limited; for example, the flexible conductive material may be platinum, aluminum, gold, silver, palladium, carbon nanotube, carbon black, a conductive polymer, or a composite material containing any combination of these materials. However, even an insulating material can be also used if a conductive layer is provided on the side facing the semiconductor electrode, and the insulating material that can be used may be a general polymer material, for example, a transparent polymer material such as polyethylene terephthalate, a polycarbonate, a polyimide or polyethylene naphthalate. Among these, polyethylene terephthalate has better heat resistance and elasticity than other materials and exhibits excellent water resistance; polycarbonate exhibits good dimensional stability and light transmittance, and particularly excellent impact resistance; while polyethylene naphthalate exhibits excellent water resistance and is moisture-proof. Thus, these polymer materials can be appropriately selected and used in accordance with the applications of the cell.

The insulating material is coated with a conductive material, and the conductive material may be a transparent material such as indium tin oxide (ITO), fluorine-doped indium tin oxide (FTO) or tin dioxide, because the light transmitted from the inner waveguide 6 passes through the counter electrode 5 and reach the sensitizer 3 (dye) in this embodiment. Platinum, gold and carbon reflect or absorb light and thus, may prevent the light transmitted from the inner waveguide 6 from reaching the sensitizer 3 (dye). However, when such conductive materials are not applied over the entire surface of the insulating material but are formed in certain patterns to secure regions for light transmittance, those materials such as platinum, gold and carbon can also be applied on the insulating material to function as the conductive material in this embodiment.

After the formation of the counter electrode 5 on the waveguide 6, the electrolyte layer 4 is formed on the counter electrode 5 to be in contact therewith. The electrolyte layer 4 includes an electrolyte. The electrolyte layer may also include the light absorbing layer 2 that is a part of the semiconductor electrode, or may infiltrate into the light absorbing layer 2. The electrolyte may be a flexible material such as liquid, gel or solid, and may be a gel or solid which can be formed cylindrically. Also, the electrolyte can be any material having a hole transferring function, for example, an iodine-based redox electrolyte, such as an electrolyte solution of I³⁻/I⁻ containing 1-methyl-3-octyl-imidazolium iodide and Lil and/or I₂ dissolved in 3-methoxypropionitrile or N-methyl-2-pyrrolidone can be used.

The semiconductor electrode is formed on the periphery of the electrolyte layer 4, and the semiconductor electrolyte includes the conductive transparent substrate 1, the light absorbing layer (metal oxide layer) 2 and the sensitizer (dye) 3.

The conductive transparent substrate 1 can be composed of a conductive transparent material that is bendable (flexible), as in the case of the counter electrode 5, and for example, an insulating material such as a polymer coated with a conductive material also can be used. In this case, the polymer used as the insulating material may be a transparent polymer material such as polyethylene terephthalate, a polycarbonate, a polyimide, or polyethylene naphthalate as described above, and the polymer material can be coated with a conductive material. The conductive material suitable for this purpose may be indium tin oxide (ITO), fluorine-doped indium tin oxide (FTO), tin oxide (for example, SnO₂) or the like, since these materials have desirable conductivity, transparency, and in particular, heat resistance. In this regard, fluorine-doped indium tin oxide (FTO) has excellent conductivity and transparency.

The metal oxide layer 2 comprises semiconductor microparticles which may consist of an element semiconductor such as silicon, a compound semiconductor, or a compound having a perovskite structure. These metal oxides may be n-type semiconductors in which electrons in the conductive band act as a carrier upon photo-excitation to supply electric current to an anode. Specifically, the metal oxide may be titanium oxide, niobium oxide, nickel oxide, copper oxide, zirconium oxide, hafnium oxide, tungsten oxide, strontium oxide, titanium strontium oxide, zinc oxide, indium oxide, tin oxide or the like; or TiO₂ (titanium dioxide), SnO₂, ZnO, WO₃, Nb₂O₅, TiSrO₃ or the like. TiO₂ with an anatase structure or rutile structure is a specific example. The semiconductor material that can be used is not limited to the species listed above, and these substances can be used individually or in combination of two or more. The semiconductor microparticles can have a large surface area so that the dye molecules adsorbed on the surface can absorb more light. Thus, the particle size of the semiconductor microparticles may be in the range of 5 to 30 nm.

In order to form the light absorbing layer (metal oxide layer) 2 using the metal oxides mentioned above, a colloidal solution is prepared from a metal oxide precursor and a solvent, and then the colloidal solution is applied on the transparent substrate 1 and calcined to induce contacting and packing of the metal oxide particles. Thus, the light absorbing layer is obtained as a calcination product. In this case, the thickness of the metal oxide layer 2 may be in the range of about 5 to 30 micrometers, so that dye molecules are sufficiently adsorbed thereon to obtain a satisfactory electron transfer effect. However, when the metal oxide layer 2 is formed cylindrically, the viscosity of the colloidal solution is insufficient, and therefore the resulting metal oxide layer 2 cannot be formed to a sufficient thickness. In this regard, a binder or the like can be added to the colloidal solution to increase the viscosity of the solution, and after the application of the colloidal solution to the substrate, the coated substrate can be dried at a low temperature, rather than to calcine at a high temperature. Further, when a metal oxide layer having sufficient thickness is not formed in a single application, it is possible to repeat the processes of applying and drying of the colloidal solution a number of times so as to form the metal oxide layer 2 with a desired thickness.

The light absorbing layer (metal oxide layer) 2 adsorbs molecules of the sensitizer (dye) 3, where the molecules of the sensitizer 3 absorb light and undergo electron transfer from the ground state(S/S⁺) to the excited state (S*/S⁺) to form electron-hole pairs. The electrons in the excited state are injected to the conduction band of the metal oxide and then move to the electrode to generate electromotive force.

The sensitizer 3 may be any material that is generally used in the art of solar cells, for example, a ruthenium complex can be used. As long as a material has a charge separation function and can be sensitized, the material is not particularly limited, and examples of such material include, in addition to ruthenium complexes, xanthine dyes such as Rhodamine B, Rose Bengal, eosin and erythrosin; cyanine dyes such as quinocyanine and kryptocyanine; basic dyes such as phenosafranin, Cabri blue, thiosine and methylene blue; porphyrin compounds such as chlorophyll, zinc porphyrin and magnesium porphyrin; other azo dyes; phthalocyanine compounds; complex compounds such as ruthenium-trisbipyridyl; anthraquinone dyes; polycyclic quinine dyes; and the like. These may be used individually or as a mixture of two or more. Examples of the ruthenium complex that can be used include RuL₂(SCN)₂, RuL₂(H₂O)₂, RuL₃, RuLL′(SCN), RuL₂ and the like (where L is 2,2′-bipyridyl-4,4′-dicarboxylate).

The cylindrical flexible solar cell according to an embodiment of the present invention can further include a protective layer in order to protect the exterior of the cell. The protective layer should not absorb ultraviolet rays, visible rays and infrared rays.

A method of producing the cylindrical flexible solar cell according to an embodiment of the present invention is not particularly limited, and a liquid coating method or an electrospinning method can be used.

The liquid coating method comprises coating the cylindrical flexible waveguide 6 with the material for the counter electrode 5, and then coating the electrolyte layer 4 thereon. Then, the light absorbing layer (metal oxide layer) 2 having the sensitizer (dye) 3 adsorbed thereon is formed on the electrolyte layer, and then the cell assembly is subjected to heat treatment to stabilize the light absorbing layer 2. If necessary, the light absorbing layer (metal oxide layer) 2 can be applied a plurality of times and then thermally treated. Subsequently, the transparent substrate 1, which is conductive and flexible, is applied onto the light absorbing layer (metal oxide layer) 2, and then a protective layer is formed on the transparent substrate 1, if necessary or desired, to complete the cylindrical flexible solar cell according to an embodiment of the present invention.

The electrospinning method is carried out by arranging slurry discharge nozzles in order for the transparent substrate 1, the light absorbing layer (metal oxide layer) 2, the sensitizer (dye) 3, the flexible electrolyte layer 4, the flexible counter electrode 5 and the flexible waveguide 6, discharging the respective slurries to form a wire, and then subjecting the wire to heat treatment to complete the cylindrical flexible solar cell according to an embodiment of the present invention. The respective element layers are as described in the above.

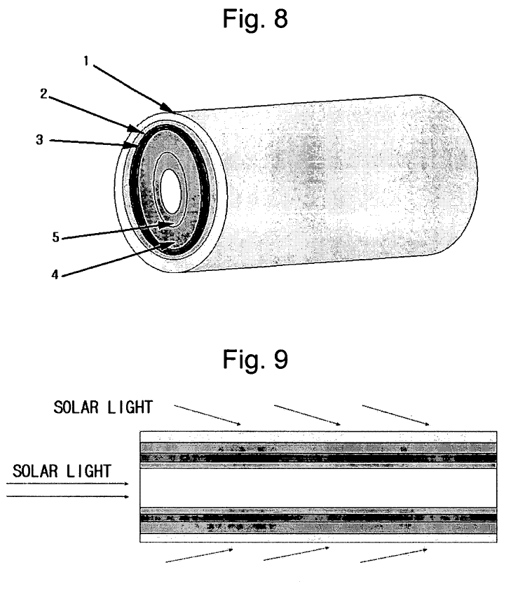

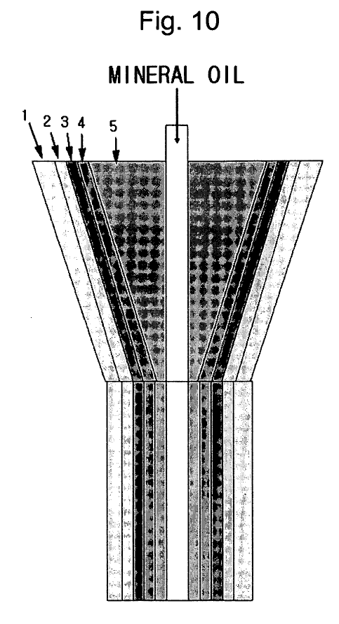

Although it is possible to produce the cylindrical flexible solar cell according to an embodiment of the present invention using either the liquid coating method or the electrospinning method, the liquid coating method is useful when the cylindrical flexible solar cell is produced in a wire form and the waveguide 6 is an optical fiber, a conductive polymer, a composite material of a conductive polymer mixed with carbon nanotubes or a conductive transparent electrode, while the electrospinning method is particularly useful when the waveguide 6 is made of a gaseous material such as air. That is, as shown in FIG. 10, in the process of arranging slurry discharge nozzles in the electrospinning method, when slurries are discharged so that a core consisting of mineral oil is formed and then the mineral oil is volatilized by heat treatment, a cylindrical flexible solar cell in the form of a tube with a hollow core as shown in FIG. 8, that is, a cylindrical flexible solar cell having a core filled with air which is used as the waveguide, is produced. The process of light absorption in the cylindrical flexible solar cell having the core filled with air as the waveguide 6 is illustrated in FIG. 9.

The mineral oil used for this purpose can be selected from generally used industrial mineral oils, and is not limited. The mineral oil can have sufficient viscosity to be capable of satisfactorily performing the role of the core axis during the process of slurry preparation, and being volatilized without leaving behind any residue during the high temperature heat treatment.

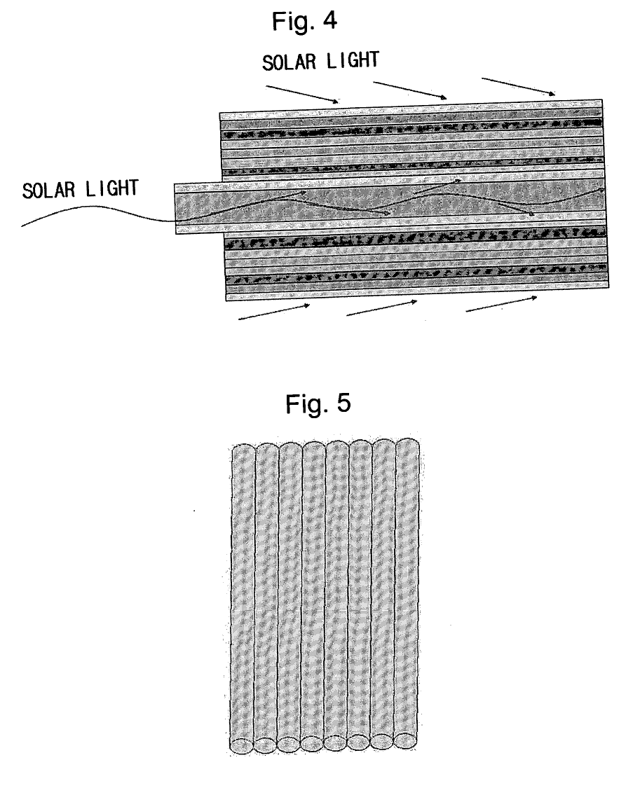

According to an embodiment of the present invention, a cylindrical flexible solar cell has a bilayer structure. The bilayer solar cell further includes a second semiconductor electrode in order to more efficiently convert solar light transmitted from the inner waveguide, and, moving toward the center, the bilayer solar cell includes a first substrate 1, a first light absorbing layer 2, a first sensitizer 3, a first electrolyte layer 4, a counter electrode 5, an electrolyte layer 4, a second sensitizer 3, a second light absorbing layer 2, a second substrate 1 and a waveguide 6, as illustrated in FIG. 3. The process of light absorption for the cylindrical bilayer flexible solar cell is illustrated in FIG. 4. In this case, light absorption can be achieved simultaneously at the outer surface and the inner surface of the cell, and thus, an improvement in the photovoltaic conversion efficiency can be expected.

More specifically, the cylindrical bilayer flexible solar cell according to an embodiment of the present invention includes, as illustrated in FIG. 3, the waveguide 6, which is cylindrical and flexible; the second substrate 1, which is flexible, transparent and conductive, and is disposed around the waveguide 6; flexible conductive transparent electrode 1 which is disposed adjacent to the waveguide; the second light absorbing layer (metal oxide layer) 2, which is disposed around the second substrate 1, has the sensitizer (dye) 3 adsorbed thereon, and is flexible; the counter electrode 5, which is disposed around the second light absorbing layer 2; the first light absorbing layer (metal oxide layer) 2, which is disposed around the counter electrode 5, has the sensitizer (dye) 3 adsorbed thereon, and is flexible; the first transparent electrode layer 1, which is disposed around the first light absorbing layer; and the first and second electrolyte layers 4, which are respectively interposed between the first and second light absorbing layers 2 and the counter electrode 5.

The respective layers constituting the cylindrical bilayer flexible solar cell according to an embodiment of the present invention are as described above, and a method of producing the cylindrical bilayer flexible solar cell is as follows.

The method of producing the cylindrical bilayer flexible solar cell according to an embodiment of the present invention includes:

coating the cylindrical flexible waveguide 6 with the second substrate 1;

coating the periphery of the substrate 1 with the second light absorbing layer 2 and then subjecting the cell assembly to heat treatment;

adsorbing the second sensitizer (dye) 3 onto the second light absorbing layer 2;

coating the periphery of the sensitizer (dye) 3 with the second electrolyte layer 4 and then applying the counter electrode 5 onto the second electrolyte layer 4;

coating the counter electrode 5 with the first electrolyte layer 4;

coating the first electrolyte layer 4 with the first light absorbing layer (metal oxide layer) 2 having a sensitizer (dye) 3 adsorbed thereon; and

subjecting the light absorbing layer 2 on which the sensitizer (dye) 3 is adsorbed to heat treatment and then coating the light absorbing layer with the first substrate 1.

In addition to the above method of production, an electrospinning apparatus can be used to produce the cylindrical flexible solar cell. Such a method includes:

preparing slurries for the first and second substrates 1, the first and second light absorbing layers (metal oxide layers) 2, the first and second sensitizers (dyes) 3, the first and second electrolyte layers 4, the counter electrode 5 and the waveguide 6, respectively;

arranging slurry discharge nozzles in order for the substrate 1, the first light absorbing layer (metal oxide layer) 2, the first sensitizer (dye) 3, the first electrolyte layer 4, the counter electrodes, the second electrolyte layer 4, the second sensitizer (dye) 3, the second light absorbing layer (metal oxide layer) 2, the waveguide 6; and

discharging the slurries through an electrospinning apparatus to form a wire; and

subjecting the wire to heat treatment.

The specific processes of the production method can be applied in the same manner as described above for the single-layer flexible solar cell.

The operation of the cylindrical flexible solar cell according to an embodiment of the present invention is as follows.

When solar light is absorbed through the outer surface of the cylindrical flexible solar cell according to an embodiment of the present invention, or through the inner light waveguide 6, the solar light reaches the light absorbing layer on which the sensitizer (dye) 3 is chemically adsorbed, and excites electrons in the dye 3 from the ground state to the excited state to form electron-hole pairs. The electrons in the excited state are injected into the conduction band of the metal oxide layer 2, and then are transferred to the transparent conductive material that is adjacent to the metal oxide layer 2, such as ITO, FTO or tin dioxide, via the interface between particles. The transferred electrons then move to the counter electrode 5 through a conducting wire connected to the transparent conductive material. The dye molecules oxidized as a result of the electron transfer are reduced again by receiving electrons that are supplied by oxidation of the iodide ions in the electrolyte layer 4, and the oxidized iodide ions are in turn reduced by the electrons arriving in the counter electrode 5, thus completing the operation of the dye-sensitized solar cell.

In the operation of the solar cell, the efficiency of energy conversion is directly proportional to the number of electrons generated by light absorption. Thus, in order to generate a large quantity of electrons, a large amount of absorbed light is required. When the solar cell is formed into a cylinder, stable light absorption is made possible regardless of the incident angle of the solar light. In particular, as the waveguide is disposed at the center so as to enable light absorption from the outside as well as the inside of the cell, thereby increasing the amount of the absorbed solar light, a larger quantity of electrons can be generated, and thus the energy conversion efficiency of the cell can be increased. In other words, stable absorption of large amounts of light is made possible.

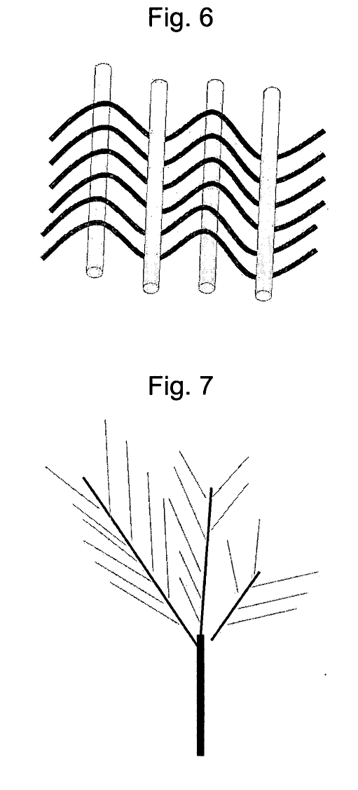

In addition, since all of the elements constituting the solar cell employ materials that can be bent (flexible), the solar cell has many applications, including commercial applications. Various examples of applications of the solar cell of an embodiment of the present invention are illustrated in FIG. 5, FIG. 6 and FIG. 7. FIG. 5 illustrates cylindrical flexible solar cells according to an embodiment of the present invention arranged in a simple array, while FIG. 6 illustrates solar cells arranged in a textile form. FIG. 7 illustrates solar cells arranged in a branched form, which is not limited by the incident angle of the solar light and is also not restricted in the form. Thus, the solar cell according to embodiments of the present invention has a wide range of fields of possible applications.

Hereinafter, the present invention will be described in more detail with reference to the following Examples and Comparative Examples. These Examples and Comparative Examples are for illustrative purpose only, and are not intended to limit the scope of the present invention.

### EXAMPLE 1

A cylindrical counter electrode was formed by sequentially coating PET and ITO on an optical fiber having a length of 5 cm and a diameter of 1 mm. A gel-like electrolyte solution of I³⁻/I⁻, produced by dissolving 0.8 M of 1,2-dimethyl-3-octyl-imidazolium iodide and 40 mM of I₂ in N-methyl-2-pyrrolidone, was coated on the cylindrical surface of the counter electrode.

Separately, a titanium dioxide colloidal solution was prepared by adding titanium isopropoxide and acetic acid to an autoclave maintained at 220° C. and carrying out hydrothermal synthesis. The obtained solution was subjected to solvent evaporation until the proportion of titanium dioxide became 12% by weight, to prepare a titanium dioxide colloidal solution containing nano-sized particles (the particle size being in the range of about 5 to 30 nm).

The cylindrical surface having the electrolyte layer formed thereon was coated with the titanium dioxide colloidal solution, and then the cell assembly was subjected to heat treatment at 150° C. Subsequently, the cell assembly was immersed in a 0.2 mM solution of ruthenium dithiocyanate 2,2′-bipyridyl-4,4′-dicarboxylate for 24 hours and dried so that the dye adsorbed onto the cell surface. The cell assembly was then coated with the titanium dioxide colloidal solution again and was thermally treated at a temperature of about 150° C. for one more hour to form a light absorbing layer having a thickness of about 10 micrometers.

Next, the titanium dioxide layer was coated with ITO and then with PET. Finally, a protective film was formed thereon to a thickness of 1 mm, thus producing a cylindrical flexible solar cell in a wire form.

### EXAMPLE 2

First, slurries for a heavy mineral oil, a counter electrode, an electrolyte layer, a metal oxide layer, a dye and a conductive transparent substrate, respectively, were prepared.

PET and ITO were used for the counter electrode and the conductive transparent substrate, respectively, and an electrolyte solution of I³⁻/I⁻ formed by dissolving 0.8 M 1,2-dimethyl-3-octyl-imidazolium and 40 mM I₂ in N-methyl-2-pyrrolidone was used for the electrolyte layer. A 0.2 mM solution of ruthenium dithiocyanate 2,2′-bipyridyl-4,4′-dicarboxylate was used as the dye.

For the metal oxide layer, a titanium dioxide colloidal solution was prepared by adding titanium isopropoxide and acetic acid to an autoclave maintained at 220° C. and carrying out hydrothermal synthesis. The obtained solution was subjected to solvent evaporation until the proportion of titanium dioxide became 12% by weight, to prepare a titanium dioxide colloidal solution containing nano-sized particles (the particle size being in the range of about 5 to 30 nm).

Using the electrospinning apparatus shown in FIG. 10, discharge nozzles containing the slurries prepared above were arranged in order for forming the conductive transparent substrate, the flexible light absorbing layer (metal oxide layer), the sensitizer (dye), the electrolyte layer, the counter electrode and the mineral oil. The thickness of the discharged wire was adjusted by adjusting the amounts of the slurries discharged from the nozzles. The obtained wire was subjected to heat treatment at 100° C. for 1 hour to volatilize the mineral oil in the core. Thus, a cylindrical flexible solar cell in a tube form was produced.

### EXAMPLE 3

A cylindrical conductive transparent electrode was formed by sequentially coating PET and ITO on the surface of an optical fiber having a length of 5 cm and a diameter of 1 mm. A gel-like electrolyte solution of I³⁻/I⁻, produced by dissolving 0.8 M of 1,2-dimethyl-3-octyl-imidazolium iodide and 40 mM of I₂ in N-methyl-2-pyrrolidone was coated on the cylindrical surface of the conductive transparent electrode.

Separately, a titanium dioxide colloidal solution was prepared by adding titanium isopropoxide and acetic acid to an autoclave maintained at 220° C. and carrying out hydrothermal synthesis. The obtained solution was subjected to solvent evaporation until the proportion of titanium dioxide became 12% by weight, to prepare a titanium dioxide colloidal solution containing nano-sized particles (the particle size being in the range of about 5 to 30 nm).

The cylindrical surface having the electrolyte layer formed thereon was coated with the titanium dioxide colloidal solution, and then the cell assembly was subjected to heat treatment at 150° C. Subsequently, the cell assembly was immersed in a 0.2 mM solution of ruthenium dithiocyanate 2,2′-bipyridyl-4,4′-dicarboxylate for 24 hours and dried so that the dye adsorbed onto the cell surface.

A cylindrical counter electrode was formed by coating the surface of an optical fiber having a length of 5 cm and a diameter of 1 mm, sequentially with PET and ITO. An electrolyte solution of I³⁻/I⁻ in which 0.8 M of 1,2-dimethyl-3-octyl-imidazolium iodide and 40 mM of I₂ were dissolved in N-methyl-2-pyrrolidone, was used as the electrolyte in gel phase to coat the cylindrical surface of the counter electrode.

Apart from this, a titanium dioxide colloidal solution was prepared by adding titanium isopropoxide and acetic acid to an autoclave maintained at 220° C. and carrying out hydrothermal synthesis therein. The obtained solution was subjected to solvent evaporation until the proportion of titanium dioxide became 12% by weight, to prepare a titanium dioxide colloidal solution containing nano-sized particles (the particle size being in the range of about 5 to 30 nm).

The cylindrical surface having the electrolyte layer formed thereon was coated with the titanium dioxide colloidal solution prepared previously, and then the cell assembly was subjected to heat treatment at 150° C. Subsequently, the cell assembly was immersed in a 0.2 mM solution of ruthenium dithiocyanate 2,2′-bipyridyl-4,4′-dicarboxylate for 24 hours and dried to have the dye adsorbed on the cell surface. A light absorbing layer having a thickness of about 10 micrometers was formed on the cell surface. Next, the titanium dioxide layer was coated with ITO and then with PET, to form a counter electrode. An electrolyte solution of I³⁻/I⁻ in which 0.8 M of 1,2-dimethyl-3-octyl-imidazolium iodide and 40 mM of I₂ were dissolved in N-methyl-2-pyrrolidone, was used as the electrolyte in gel phase to coat the cylindrical surface of the counter electrode.

Apart from this, a titanium dioxide colloidal solution was prepared by adding titanium isopropoxide and acetic acid to an autoclave maintained at 220° C. and carrying out hydrothermal synthesis therein. The obtained solution was subjected to solvent evaporation until the proportion of titanium dioxide became 12% by weight, to prepare a titanium dioxide colloidal solution containing nano-sized particles (the particle size being in the range of about 5 to 30 nm).

The cylindrical surface having the electrolyte layer formed thereon was coated with the titanium dioxide colloidal solution prepared previously, and then the cell assembly was subjected to heat treatment at 150° C. Subsequently, the cell assembly was immersed in a 0.2 mM solution of ruthenium dithiocyanate 2,2′-bipyridyl-4,4′-dicarboxylate for 24 hours and dried to have the dye adsorbed on the cell surface. A light absorbing layer having a thickness of about 10 micrometers was formed on the cell surface.

Next, the titanium dioxide layer was coated with ITO and then with PET. Finally, a protective film was formed thereon to a thickness of 1 mm, and the desired cylindrical flexible solar cell in a wire form was thus produced.

### EXAMPLE 4

First, slurries for a heavy mineral oil, a counter electrode, an electrolyte layer, a metal oxide layer, a dye and a conductive transparent substrate, respectively, were prepared.

PET and ITO were used for the conductive transparent substrate and the counter electrode, respectively, and an electrolyte solution of I³⁻/I⁻ formed by dissolving 0.8 M 1,2-dimethyl-3-octyl-imidazolium and 40 mM I₂ in N-methyl-2-pyrrolidone was used for the electrolyte layer. A 0.2 mM solution of ruthenium dithiocyanate 2,2′-bipyridyl-4,4′-dicarboxylate was used as the dye.

For the metal oxide layer, a titanium dioxide colloidal solution was prepared by adding titanium isopropoxide and acetic acid to an autoclave maintained at 220° C. and carrying out hydrothermal synthesis. The obtained solution was subjected to solvent evaporation until the proportion of titanium dioxide became 12% by weight, to prepare a titanium dioxide colloidal solution containing nano-sized particles (the particle size being in the range of about 5 to 30 nm).

Using the electrospinning apparatus shown in FIG. 10, discharge nozzles containing the slurries prepared above were arranged in order for forming the conductive flexible transparent substrate, the light absorbing layer (metal oxide layer), the sensitizer (dye), the electrolyte layer, the counter electrode, the electrolyte layer, the sensitizer (dye), the light absorbing layer (metal oxide layer) and the mineral oil. The thickness of the discharged wire was adjusted by adjusting the amounts of the slurries discharged from the nozzles. The obtained wire was subjected to heat treatment at 100° C. for 1 hour to volatilize the mineral oil in the core. Thus, a cylindrical flexible solar cell in a tube form was produced.

### COMPARATIVE EXAMPLE 1

A titanium dioxide colloidal solution was prepared by adding titanium isopropoxide and acetic acid to an autoclave maintained at 220° C. and carrying out hydrothermal synthesis. The obtained solution was subjected to solvent evaporation until the proportion of titanium dioxide became 12% by weight, to prepare a titanium dioxide colloidal solution containing nano-sized particles (the particle size being in the range of about 5 to 30 nm).

Next, hydroxypropylcellulose (molecular weight 80,000) was added to the concentrated metal oxide solution, and then the mixture was stirred for 24 hours to produce a slurry for titanium dioxide coating. Subsequently, a transparent conductive glass substrate which was coated with indium tin oxide (ITO) and had a transmittance of 80% was coated with the slurry for titanium dioxide coating using a the doctor blade coating technique. Then, the coated substrate was subjected to heat treatment at a temperature of about 450° C. for 1 hour, to allow contacting and packing between the nano-sized oxide particles, excluding the organic polymer, and thus a conductive, transparent substrate having a thickness of 10 micrometers was obtained. A titanium dioxide layer with a thickness of about 6 micrometers was formed on the surface of the conductive, transparent substrate.

Subsequently, the conductive, transparent substrate having the titanium dioxide layer formed thereon was immersed in a 0.2 mM solution of ruthenium dithiocyanate 2,2′-bipyridyl-4,4′-dicarboxylate solution for 24 hours and then dried to allow the dye to adsorb onto the substrate.

A counter electrode was produced by coating the ITO-coated surface of the conductive, transparent glass substrate with platinum. Subsequently, the counter electrode and the semiconductor electrode were assembled as an anode and a cathode, respectively. The two electrodes were assembled such that the conductive surfaces of the anode and cathode were disposed toward the interior of the cell, such that the platinum layer and the light absorbing layer faced each other. A polymer sheet made of SURLYN (Du Pont Corp.) and having a thickness of about 40 micrometers was interposed between the anode and the cathode, and the two electrodes were compressed at a pressure of about 1 to 3 atm on a heating plate at about 100 to 140° C. The polymer was adhered to the surfaces of the two electrodes by heat and pressure.

Next, an electrolyte solution was injected into the gap between the two electrodes through the micropores formed on the surface of the anode, and thus a conventional dye-sensitized solar cell was completed. The electrolyte solution was an electrolyte solution of I³⁻/I⁻ obtained by dissolving 0.8 M of 1,2-dimethyl-3-octyl-imidazolium and 40 mM of I₂ in N-methyl-2-pyrrolidone.

### EXPERIMENTAL EXAMPLE

The photovoltage and photocurrent of the dye-sensitized solar cells produced in Examples 1 through 4 and Comparative Example 1 above were measured in order to determine the photovoltaic conversion efficiencies of the solar cells.

A xenon lamp (Oriel Instruments, Inc., 01193) was used as a light source, and the solar conditions for the xenon lamp were corrected by using a standard solar cell (Frunhofer Institute Solare Engeriessysteme, Certificate No. C-ISE369, type of material: Mono-Si+KG filter). The photovoltaic conversion efficiency (ηₑ) obtained by using the current density (I_{sc}), voltage (V_{oc}) and fill factor (FF) which were calculated from a measured photocurrent-voltage curve, is presented in the following Table 1. The formula for the photovoltaic conversion efficiency is as follows:
ηₑ=(V_{oc}I_{sc}FF)/(P_{inc})

wherein P_{inc} is 100 mW/cm² (1 sun).

TABLE 1

| | Photoconversion efficiency (%) |
|---|---|
| Example 1 | 4.8 |
| Example 2 | 4.7 |
| Example 3 | 5.2 |
| Example 4 | 5.1 |
| Comparative Example 1 | 3.6 |

As can be seen from the results of Table 1, the cylindrical flexible solar cell of certain exemplary embodiments of the present invention exhibits an increase in the energy conversion efficiency due to the waveguide located inside the cell, allows a reduction in the installation area and stable energy conversion because of the cylindrical structure, and is bendable because of the use of flexible materials. Thus, various flexible solar cell in accordance with the present invention can be applicable to various areas and designs.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A cylindrical flexible solar cell including:
a cylindrical flexible waveguide;
a flexible counter electrode disposed around the waveguide;
a flexible light absorbing layer that is disposed around the counter electrode and has a sensitizer adsorbed thereon;
a conductive transparent electrode layer disposed around the flexible light absorbing layer; and
a flexible electrolyte layer interposed between the light absorbing layer and the counter electrode.

2. The cylindrical flexible solar cell of claim 1, wherein the cylindrical flexible waveguide is made of one of: an optical fiber, air, a conductive polymer, a composite material comprising a conductive polymer mixed with carbon nanotubes, and a conductive transparent electrode.

3. The cylindrical flexible solar cell of claim 2, wherein the cylindrical flexible waveguide is one of an optical fiber and air.

4. The cylindrical flexible solar cell of claim 1, wherein the flexible counter electrode is formed of a non-conductive polymer material and a conductive material.

5. The cylindrical flexible solar cell of claim 4, wherein the non-conductive polymer material includes at least one polymer selected from the group consisting of polyethylene terephthalate, polycarbonates, polyimides and polyethylene naphthalate.

6. The cylindrical flexible solar cell of claim 4, wherein the conductive material is one of: indium tin oxide, FTO, carbon nanotube, a conductive polymer, a composite material comprising a conductive polymer mixed with carbon nanotubes, and tin dioxide.

7. The cylindrical flexible solar cell of claim 1, wherein the conductive transparent electrode layer is formed of a non-conductive polymer material and a conductive material.

8. The cylindrical flexible solar cell of claim 7, wherein the non-conductive polymer material includes at least one polymer selected from the group consisting of polyethylene terephthalate, polycarbonate, polyimide and polyethylene naphthalate.

9. The cylindrical flexible solar cell of claim 6, wherein the conductive material is one of: indium tin oxide and tin dioxide.

10. The cylindrical flexible solar cell of claim 1, wherein the flexible electrolyte layer is in one of: a gel phase and a solid phase.

11. A cylindrical flexible solar cell including:
a cylindrical flexible waveguide;
a flexible conductive transparent electrode disposed adjacent to the waveguide;
a first flexible light absorbing layer that is disposed around the flexible conductive transparent electrode and has a sensitizer adsorbed thereon;
a flexible counter electrode disposed around the first flexible light absorbing layer;
a second flexible light absorbing layer that is disposed around the counter electrode and has a sensitizer adsorbed thereon;
a conductive transparent electrode layer disposed around the second flexible light absorbing layer; and
flexible electrolyte layers respectively interposed between the first and second light absorbing layers and the counter electrode.

12. The cylindrical flexible solar cell of claim 11, wherein the cylindrical flexible waveguide is made of one of: an optical fiber, air, a conductive polymer, a composite material comprising a conductive polymer mixed with carbon nanotubes, and a conductive transparent electrode.

13. The cylindrical flexible solar cell of claim 12, wherein the cylindrical flexible waveguide is one of an optical fiber and air.

14. The cylindrical flexible solar cell of claim 11, wherein the flexible counter electrode is formed of a non-conductive polymer material and a conductive material.

15. The cylindrical flexible solar cell of claim 14, wherein the non-conductive polymer material includes at least one polymer selected from the group consisting of polyethylene terephthalate, polycarbonates, polyimides and polyethylene naphthalate.

16. The cylindrical flexible solar cell of claim 14, wherein the conductive material is one of: indium tin oxide, FTO, carbon nanotube, a conductive polymer, a composite material comprising a conductive polymer mixed with carbon nanotubes, and tin dioxide.

17. The cylindrical flexible solar cell of claim 11, wherein the conductive transparent electrode layer is formed of a non-conductive polymer material and a conductive material.

18. The cylindrical flexible solar cell of claim 17, wherein the non-conductive polymer material includes at least one polymer selected from the group consisting of polyethylene terephthalate, polycarbonate, polyimide and polyethylene naphthalate.

19. The cylindrical flexible solar cell of claim 16, wherein the conductive material is one of: indium tin oxide and tin dioxide.

20. The cylindrical flexible solar cell of claim 11, wherein the flexible electrolyte layer is in one of: a gel phase and a solid phase.

21. A method of producing a cylindrical flexible solar cell comprising:
coating a cylindrical flexible waveguide with a material to form a counter electrode;
coating the counter electrode with a flexible electrolyte layer;
coating the flexible electrolyte layer with a light absorbing layer having a sensitizer adsorbed thereon; and
subjecting the light absorbing layer to heat treatment after the coating and then coating the light absorbing layer with a conductive flexible transparent substrate.

22. The method of claim 21, wherein the conductive flexible transparent substrate contains a non-conductive polymer and a conductive material.

23. The method of claim 21, wherein the flexible counter electrode contains a non-conductive polymer and a conductive material.

24. The method of claims 21, wherein the flexible waveguide is formed of one of an optical fiber, air, a conductive polymer a composite material having a conductive polymer mixed with carbon nanotubes, and a conductive transparent electrode.

25. A method of producing a flexible solar cell comprising:
coating a cylindrical flexible waveguide with a first conductive flexible transparent substrate;
coating the conductive, flexible transparent substrate with a first light absorbing layer and subjecting the first light absorbing layer to heat treatment;
adsorbing a sensitizer onto the first light absorbing layer;
coating the sensitizer with an electrolyte layer and then coating the electrolyte layer with a flexible counter electrode;
coating the counter electrode with a flexible electrolyte layer;
coating the flexible electrolyte layer with a second light absorbing layer having a sensitizer adsorbed thereon; and
subjecting the second light absorbing layer to heat treatment after the coating of the flexible electrolyte layer and then coating the second light absorbing layer with a second conductive flexible transparent substrate.

26. The method of claim 25, wherein the conductive flexible transparent substrate contains a non-conductive polymer and a conductive material.

27. The method of claim 25, wherein the flexible counter electrode contains a non-conductive polymer and a conductive material.

28. The method of claim 25, wherein the flexible waveguide is formed of one of an optical fiber, air, a conductive polymer a composite material having a conductive polymer mixed with carbon nanotubes, and a conductive transparent electrode.

29. A method of producing a cylindrical flexible solar cell comprising:
preparing slurries for conductive flexible transparent substrates, flexible light absorbing layers, sensitizers, flexible electrolyte layers, a flexible counter electrode and a flexible waveguide, respectively;
arranging slurry discharge nozzles in order for a conductive flexible transparent substrate, a flexible light absorbing layer, a sensitizer, a flexible electrolyte layer, a flexible counter electrode, and a flexible waveguide; or in order for a conductive flexible transparent substrate, a first flexible light absorbing layer, a first sensitizer, a first flexible electrolyte layer, a flexible counter electrode, a second flexible electrolyte layer, a second sensitizer, a second flexible light absorbing layer, and a flexible waveguide; and
discharging the slurries through an electrospinning apparatus to form a wire and;
subjecting the wire to heat treatment.

30. The method of claim 29, wherein the conductive flexible transparent substrate contains a non-conductive polymer and a conductive material.

31. The method of claim 29, wherein the flexible counter electrode contains a non-conductive polymer and a conductive material.

32. The method of claim 29, wherein the flexible waveguide is formed of one of an optical fiber, air, a conductive polymer a composite material having a conductive polymer mixed with carbon nanotubes, and a conductive transparent electrode.
